(19) United States
(12) Patent Application Publication
(10) Pub. No.: US 2026/0352089 A1
(43) Pub. Date: Nov. 5, 2026

(54) DRIVE CIRCUIT

(71) Applicant: Minebea Power Semiconductor Device Inc., Hitachi-shi, Ibaraki (JP)

(72) Inventors: Kazuki TANI, Tokyo (JP); Kenji HARA, Tokyo (JP)

(21) Appl. No.: 19/487,651

(22) PCT Filed: Feb. 15, 2024
(86) PCT No.: PCT/JP2024/005213

§ 371 Date: Nov. 25, 2025

(30) Foreign Application Priority Data
Jun. 5, 2023 (JP) 2023-092677

(51) Int. Cl. H02M 1/08; H02M 3/156

(52) U.S. Cl. CPC H02M 1/08; H02M 3/156

(57) ABSTRACT

A drive circuit for a power conversion device includes a gate driver for driving a collector gate (CG) of a CG-IGBT serving as an upper-arm output element and has a charge storage circuit including a capacitor and a backflow prevention element and a charging/discharging control circuit including a switching element and a resistor. One terminal of the capacitor is connected to a main power supply of the power conversion device via the backflow prevention element and connected to the collector gate of the CG-IGBT. Another terminal of the capacitor is connected to a reference potential of the power conversion device via the switching element and connected to the main power supply of the power conversion device via the resistor.

### TECHNICAL FIELD

The present invention relates to a drive circuit for a power conversion device.

### BACKGROUND ART

With the growing global awareness of environmental conservation, a demand for energy saving is further increasing, and power conversion devices have been widely adopted in various fields. In a power conversion device to be mounted on a drive system of a railway vehicle, an air conditioner, or the like, a size reduction, a weight reduction, and higher reliability, as well as higher performance and higher efficiency, have become important issues.

An insulated gate bipolar transistor (IGBT) is used in, e.g., a circuit of an inverter having an inductive load. A typical IGBT has a collector terminal and an emitter terminal that cut off a voltage or conduct a current, and a gate terminal that controls a cut-off state and a conductive state of the IGBT. In order to reduce a resistance of the IGBT when the IGBT is conducting, it is effective to inject carriers at a high density into a drift layer to promote conductivity modulation.

Meanwhile, when carriers are injected at a high density into the drift layer, a speed of a turn-off switching operation in which the IGBT shifts from the conductive state to the cut-off state decreases, which results in a disadvantage of an increased turn-off loss, and reductions of a conduction loss and the turn-off loss have a trade-off relationship therebetween. In recent years, as one means for improving the trade-off relationship, there is a collector gate control IGBT (CG-IGBT) in which an N-type MOSFET structure is added to a collector portion and which further has a collector gate terminal (CG) for controlling the N-type MOSFET of the collector portion, and Patent Literature 1 discloses a drive circuit for driving and controlling the CG of the CG-IGBT.

The drive circuit for driving and controlling the CG of the CG-IGBT in Patent Literature 1 discloses an example that generate a power supply voltage for CG driving using a bootstrap circuit. Meanwhile, Patent Literature 2 discloses a drive circuit for driving and controlling a conventional emitter-side gate of an upper-arm-side output element, and discloses a configuration in which the emitter-side gate of the upper-arm-side output element is charged from a main power supply of a power conversion device.

In the present document, a CG-IGBT is described as a concept indicating an IGBT including an emitter, a collector, and an emitter gate (conventional gate), which is an emitter-side gate, and a collector gate (CG), which is a collector-side gate. In addition, the CG-IGBT is described as a type of the CG-IGBT including a collector-gate controlled reverse-conducting IGBT (CG-RC-IGBT).

### CITATION LIST

### Patent Literatures

Patent Literature 1: Japanese Patent Application Publication No. 2023-35478

Patent Literature 2: Japanese Patent Application Publication No. 2022-24572

### SUMMARY OF INVENTION

### Technical Problem

Since a collector potential of the CG-IGBT of the upper-arm output element on an upper-arm side of the power conversion device is equal to a potential of a main power supply of the power conversion device, when the CG is turned ON, it is necessary to set a potential at the CG higher than the main power supply of the power conversion device. This results in a problem in that, to driving and controlling of the CG of the CG-IGBT of the upper-arm output element on the upper-arm side of the power conversion device, power supply generation using the boot strap circuit, which is disclosed in Patent Literature 1, and a method of direct charging from the main power supply of the power conversion device, which is disclosed in Patent Literature 2, cannot be applied.

It is therefore an object of the present invention to provide, in a power conversion device having a bridge circuit including upper and lower arms, an upper-arm drive circuit capable of driving and controlling a CG of a CG-IGBT of an upper-arm output element on an upper-arm side and achieving a size reduction and higher efficiency of the power conversion device as well as a control method thereof.

### Solution to Problem

A drive circuit for a power conversion device as an embodiment of the present invention is characterized in that a gate driver for driving a collector gate of a CG-IGBT serving as an upper-arm output element has a charge storage circuit including a capacitor and a backflow prevention element and a charging/discharging control circuit including a switching element and a resistor, one terminal of the capacitor is connected to a main power supply of the power conversion device via the backflow prevention element and connected to the collector gate of the CG-IGBT, and another terminal of the capacitor is connected to a reference potential of the power conversion device via the switching element and connected to the main power supply of the power conversion device via the resistor.

### Advantageous Effects of Invention

According to the present invention, in a power conversion device having a bridge circuit including upper and lower arms, it is possible to implement an upper-arm drive circuit capable of driving and controlling a CG of a CG-IGBT of an upper-arm output element on an upper-arm side and achieving a size reduction and higher efficiency of the power conversion device as well as a control method thereof.

### BRIEF DESCRIPTION OF DRAWINGS

FIG. 1 is a partial cross-sectional structural view illustrating a part of a CG-IGBT according to a first embodiment of the present invention.

FIG. 2(a) is an equivalent circuit diagram of a CG-(RC-) IGBT according to the first embodiment of the invention and FIG. 2(b) illustrates symbols for the CG-(RC-) IGBT.

FIG. 3 is a diagram illustrating a specific example of an upper-arm drive circuit according to the first embodiment of the present invention.

FIG. 4 is a timing chart illustrating an operation of the upper-arm drive circuit according to the first embodiment of the present invention.

FIG. 5 is a diagram illustrating a modification of the upper-arm drive circuit according to the first embodiment of the present invention.

FIG. 6 is a diagram illustrating a specific example of an upper-arm drive circuit according to a second embodiment of the present invention.

FIG. 7 is a diagram illustrating a modification of the upper-arm drive circuit according to the second embodiment of the present invention.

FIG. 8 is a timing chart illustrating an operation of the upper-arm drive circuit according to the second embodiment of the present invention.

FIG. 9 is a diagram illustrating a specific example of an upper-arm drive circuit according to a third embodiment of the present invention.

FIG. 10 is a diagram illustrating a modification of the upper-arm drive circuit according to the third embodiment of the present invention.

FIG. 11 is a diagram illustrating a specific example of an upper-arm drive circuit according to a fourth embodiment of the present invention.

FIG. 12 is a timing chart illustrating an operation of the upper-arm drive circuit according to the fourth embodiment of the present invention.

FIG. 13 is a diagram illustrating specific examples of an upper-arm drive circuit and a lower-arm drive circuit according to a fifth embodiment of the present invention.

FIG. 14 is a timing chart illustrating operations of the upper-arm drive circuit and the lower-arm drive circuit according to the fifth embodiment of the present invention.

### DESCRIPTION OF EMBODIMENTS

Referring to the drawings, embodiments of the present invention will be described below. In the individual drawings, the same reference signs denote the same components, and detailed descriptions thereof will not be repeated.

### First Embodiment

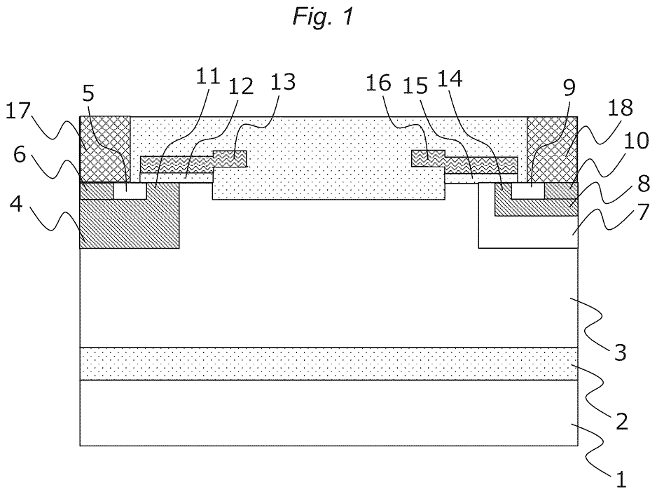

FIG. 1 is a partial cross-sectional structural view illustrating a portion of a CG-IGBT in the first embodiment. As illustrated in FIG. 1, a buried oxide film 2 is formed on a support substrate 1 made of silicon (Si), a p-base region 4 is selectively formed in a surface layer of an n-type semiconductor layer 3, an n-emitter region 5 is formed in a portion of a surface layer of the p-base region 4, and a p-anode region 6 is formed adjacent to the n-emitter region 5. Meanwhile, an n-buffer region 7 is selectively formed in a different region of the surface layer of the n-type semiconductor layer 3, a p-base region 8 is formed in a portion of a surface layer of the n-buffer region 7, an n-cathode region 9 is formed in a portion of a surface layer of the p-base region, and a p-collector region 10 is formed in another portion of the surface layer of the p-base region.

A gate electrode 13 to be connected to a gate terminal (G) via a gate oxide film 12 is provided on a surface of a channel region 11 in the surface layer of the p-base region 4, and a collector gate electrode 16 to be connected to a collector gate terminal (CG) via a gate oxide film 15 is formed on a surface of the channel region 14 in a surface layer of the p-base region 8. In addition, an emitter electrode 17 is provided in common contact with respective surfaces of the n-emitter region 5 and the p-anode region 6, a collector electrode 18 is provided in common contact with respective surfaces of the p-collector region 10 and the n-cathode region 9, and the emitter electrode 17 and the collector electrode 18 are connected respectively to an emitter terminal (E) and a collector terminal (C).

While a description is given herein by using a CG-RC-IGBT as an example of the CG-IGBT, the present invention is not limited to thereto, and a CG-IGBT, which is not a reverse-conducting IGBT (RC-IGBT), may also be used.

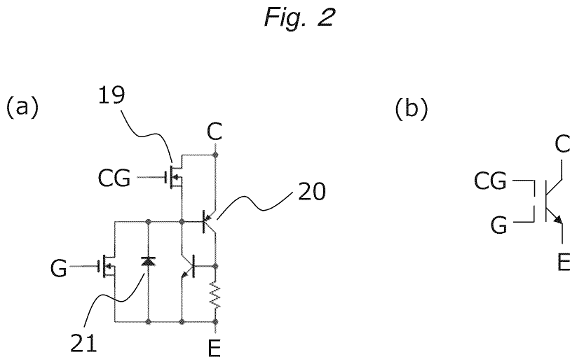

FIG. 2(a) is an equivalent circuit diagram of the CG-(RC-)IGBT in the first embodiment, and FIG. 2(b) illustrates symbols indicating the CG-(RC-)IGBT in the first embodiment. As illustrated in FIG. 2(a), the CG-(RC-)IGBT of the present invention includes an N-type MOSFET 19 and an embedded diode 21, as compared to a typical IGBT. The N-type MOSFET 19 is of a normally-off type, and turning ON/OFF thereof is controlled by a collector gate CG.

When the collector gate CG is in an OFF state (an N-type MOSFET 19 is OFF), the same operation as that of the typical IGBT is performed. When the collector gate CG is in the OFF state and a gate G (which is also referred to as an emitter gate corresponding to an emitter on an emitter side, but is simply referred to as “gate” since the gate G corresponds to a conventional gate) is in the OFF state, between a collector C and an emitter E, a cut-off state is provided in a forward direction. When the collector gate CG is in the OFF state and the gate G is in an ON state, the CG-(RC-)IGBT is rendered conductive by a bipolar operation, similarly to the typical IGBT.

When the gate G is ON and the collector gate CG is the ON state (the N-type MOSFET 19 is ON), a short circuit occurs between the base and the emitter of a pnp transistor 20 to turn OFF the pnp transistor 20, and therefore the CG-(RC-)IGBT operates as a unipolar element in which only an electron current flows via each of the channel region 11, the n-type semiconductor layer 3, and the channel region 14. When a conducting current becomes large and a voltage drop between the drain and the source of the N-type MOSFET 19 becomes large, a voltage is generated between the base and the emitter of the pnp transistor 20 to turn ON the pnp transistor 20, which allows a bipolar operation.

Meanwhile, in a case of the CG-RC-IGBT, in a state where the collector gate CG is ON, the gate G is OFF, and the N-type MOSFET 19 is ON, a reverse-conducting current can be allowed to flow via the embedded diode 21 and the N-type MOSFET 19. In a state where the collector gate CG is ON, and the gate G is ON when the reverse-conducting current is allowed to flow, a short circuit occurs between the anode and the cathode of the embedded diode 21 and no current flows through the embedded diode 21, the CG-RC-IGBT performs unipolar operation in which only an electron current flows via each of the channel region 11, the n-type semiconductor layer 3, and the channel region 14. In the present embodiment, the CG-(RC-)IGBT will be represented by the symbols shown in FIG. 2(b).

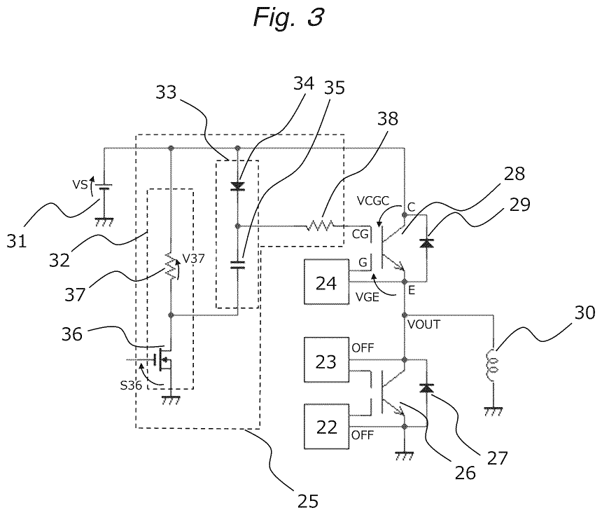

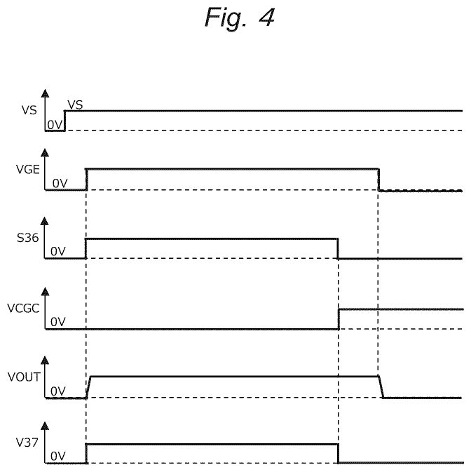

FIG. 3 is a diagram illustrating a schematic configuration of an upper-arm drive circuit for a power conversion device in the first embodiment of the present invention, and FIG. 4 is a timing chart illustrating an operation of thereof. Note that the following description will be given by using an example of a half-bridge circuit configured to include one leg having, as output elements, upper and lower arms each including a CG-IGBT and a freewheeling diode, but the subject matter of the present invention is not limited thereto. The present invention is also applicable to a power conversion device of a three-phase full-bridge circuit configured by connecting another additional leg to the half-bridge circuit to provide a full-bridge configuration and connecting a three-phase ac output terminal (in U-, V-, and W-phases) to a neutral point of each of the legs.

In FIG. 3, a CG-IGBT 28 and a freewheeling diode 29 are upper-arm output elements of the power conversion device, and a CG-IGBT 26 and a freewheeling diode 27 are lower-arm output elements of the power conversion device. As shown in FIG. 3, in the power conversion device in the first embodiment of the present invention, a load (coil) 30 is connected to an output terminal VOUT (the emitter E of the CG-IGBT 28 and the collector C of the CG-IGBT 26), the collector C of the CG-IGBT 28 is connected to the main power supply 31, the upper-arm drive circuit includes a gate driver 24 which drives the gate G of the CG-IGBT 28 and a gate driver 25 which drives the collector gate CG thereof, and the lower-arm drive circuit includes a gate driver 22 which drives the gate G of the CG-IGBT 26 and a gate driver 23 which drives the collector gate CG thereof.

The gate driver 25 includes a charge storage circuit 33 having a backflow prevention element (diode) 34 and a capacitor 35, a charging/discharging control circuit 32 having a resistor 37 and a switching element 36, and a gate delay circuit (resistor) 38. The charging/discharging control circuit 32 is provided between the main power supply 31 of the power conversion device and a reference potential (ground) of the power conversion device, and the charge storage circuit 33 is connected in parallel with the resistor 37 of the charging/discharging control circuit 32.

Furthermore, one terminal of the capacitor 35 is connected to the main power supply 31 of the power conversion device via the backflow prevention element (diode) 34 and connected to the collector gate CG of the CG-IGBT 28 via the gate delay circuit (resistor) 38, while another terminal of the capacitor 35 is connected to the main power supply 31 of the power conversion device via the resistor 37 and connected to the reference potential (ground) of the power conversion device via the switching element 36. The main power supply 31 of the power conversion device and the collector gate CG of the CG-IGBT 28 are connected via each of the backflow prevention element (diode) 34 and the gate delay circuit (resistor) 38.

As shown in FIG. 4, in the upper-arm drive circuit for the power conversion device in the first embodiment of the present invention, the main power supply 31 is turned ON first to increase a collector voltage of the CG-IGBT 28 to a voltage VS of the main power supply 31. Then, in response to an upper-arm ON command signal input to the gate driver 24, a gate voltage VGE rises to turn ON the CG-IGBT 28, and the output terminal VOUT rises to the voltage VS of the main power supply 31 of the power conversion device.

At this time, by turning ON the switching element 36, a positive voltage V37 is generated across both ends of the resistor 37, and charges are stored in the capacitor 35. Thereafter, when the switching element 36 is turned OFF, no current flows in the resistor 37, the voltage V37 between the both ends of the resistor 37 drops to 0 V, and a potential at a junction between the resistor 37, the switching element 36, and the other terminal of the capacitor 35 becomes equal to the voltage VS of the main power supply 31 of the power conversion device. As a result, the charges stored in the capacitor 35 are injected into the collector gate CG of the CG-IGBT 28 via the gate delay circuit (resistor) 38 to increase the voltage of the collector gate CG, bring the collector gate of the CG-IGBT 28 into the ON state, and reduce a carrier density in the CG-IGBT 28.

Thereafter, in response to an upper-arm OFF command signal input to the gate driver 24, the gate voltage VGE drops to turn OFF the CG-IGBT 28, and the output terminal VOUT drops to the reference potential (ground) of the power conversion device.

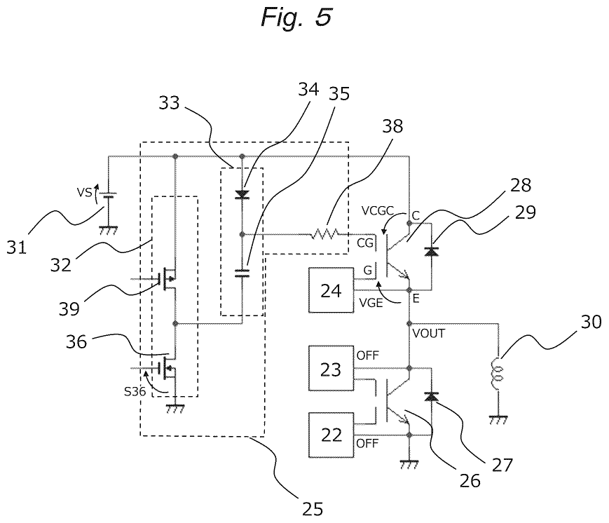

As has been described above, with the upper-arm drive circuit and the control method thereof in the first embodiment of the present invention, by turning ON the collector gate CG of the CG-IGBT 28 prior to turning OFF of the CG-IGBT 28, it is possible to reduce the carrier density in the CG-IGBT 28, and consequently reduce a turn-off loss of the CG-IGBT 28. As a modification of the first embodiment of the present invention, as shown in FIG. 5, it may also be possible to replace the resistor 37 with the switching element 39 and perform control such that the switching element 39 is OFF during a period during which the switching element 36 is ON and that the switching element 39 is OFF during a period during which the switching element 36 is OFF.

### Second Embodiment

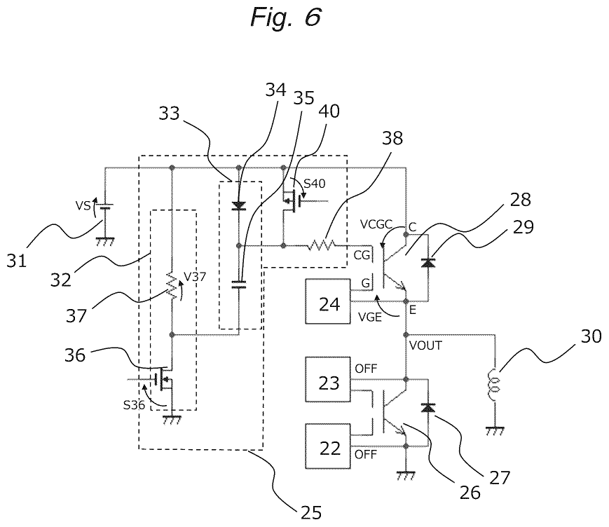

Next, referring to FIGS. 6 to 8, a configuration of an upper-arm drive circuit and a control method thereof in a second embodiment of the present invention will be described. A difference between FIG. 6 and FIG. 3 is that, in FIG. 6, a switching element 40 for turning OFF the collector gate CG is connected between the collector gate CG and the collector C of the CG-IGBT 28. In a configuration in FIG. 3, as shown in the timing chart of FIG. 4, to maintain the collector gate CG in the OFF state, it is necessary to maintain the switching element 36 in the ON state.

In the second embodiment of the present invention shown in FIG. 6, by turning ON the switching element 40 while the switching element 36 is in the OFF state, it is possible to cause a short circuit between the collector gate CG and the collector C of the CG-IGBT 28, discharge the charges stored in the capacitor 35, and maintain the collector gate CG of the CG-IGBT 28 in the OFF state.

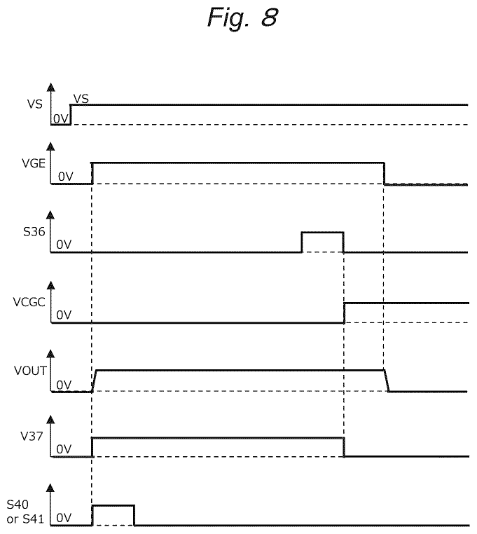

FIG. 8 illustrates a timing chart showing an operation of the upper-arm drive circuit in the second embodiment of the present invention. When the CG-IGBT 28 is turned ON, the switching element 40 is turned ON to maintain the OFF state of the collector gate CG of the CG-IGBT 28, the switching element 36 is turned ON prior to the turning OFF of the CG-IGBT 28 to store charges in the capacitor 35, and subsequently the switching element 36 is turned OFF to inject the charges stored in the capacitor 35 into the collector gate CG of the CG-IGBT 28 to be able to turn ON the collector gate CG.

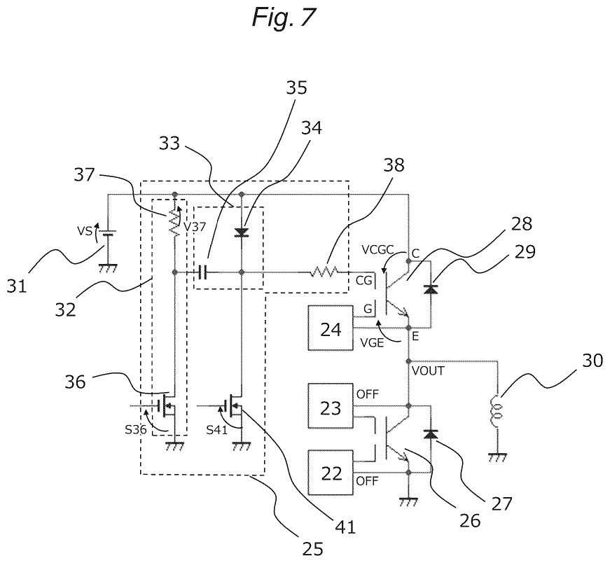

As described above, with the upper-arm drive circuit and the control method thereof in the second embodiment of the present invention, it is possible to reduce a period during which the switching element 36 is ON, and therefore it is possible to reduce power consumed by the charging/discharging control circuit 32. As a modification of the second embodiment of the present invention, as shown in FIG. 7, instead of the switching element 40, a switching element 41 may also be connected between the collector gate CG of the CG-IGBT 28 and the reference potential (ground) of the power conversion device.

### Third Embodiment

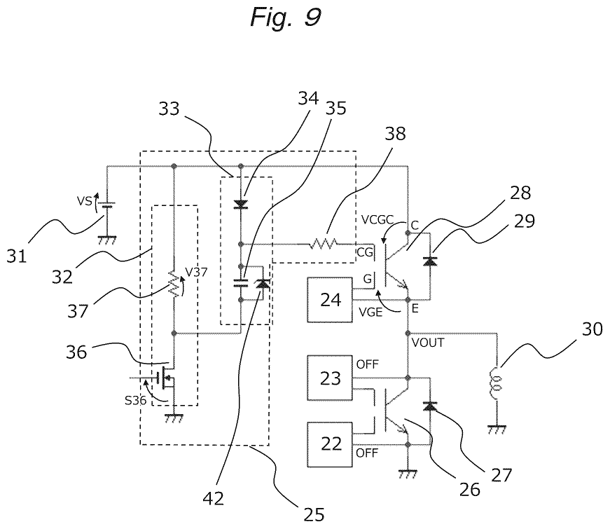

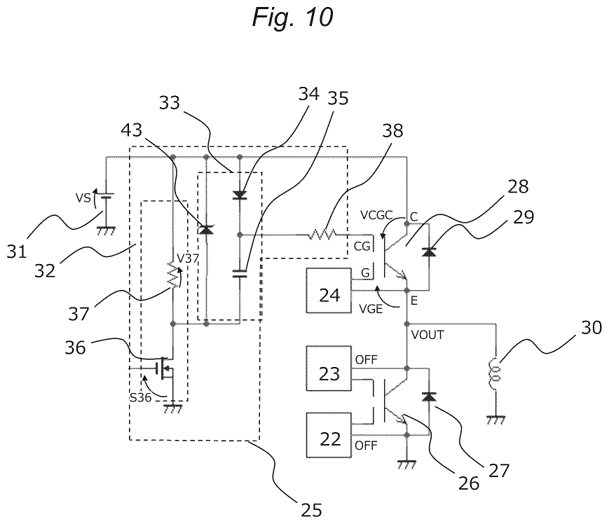

Next, referring to FIG. 9 and FIG. 10, a configuration of an upper-arm drive circuit in a third embodiment of the present invention will be described. A difference between FIG. 3 and FIG. 9 is that, in FIG. 9, a voltage limiting element (zener diode) 42 is connected in parallel to the capacitor 35.

In the third embodiment of the present invention shown in FIG. 9, when the switching element 36 is turned ON, the voltage limiting element (zener diode) 42 can limit the voltage applied to the capacitor 35, and therefore it is possible to prevent an overvoltage from being applied to the collector gate CG when charges are injected into the collector gate CG of the CG-IGBT 28 by turning OFF the switching element 36, which allows reliability of the CG-IGBT 28 to be improved. Note that, as a modification of the third embodiment of the present invention, as shown in FIG. 10, a voltage limiting element (zener diode) 43 may also be connected in parallel to the resistor 37.

### Fourth Embodiment

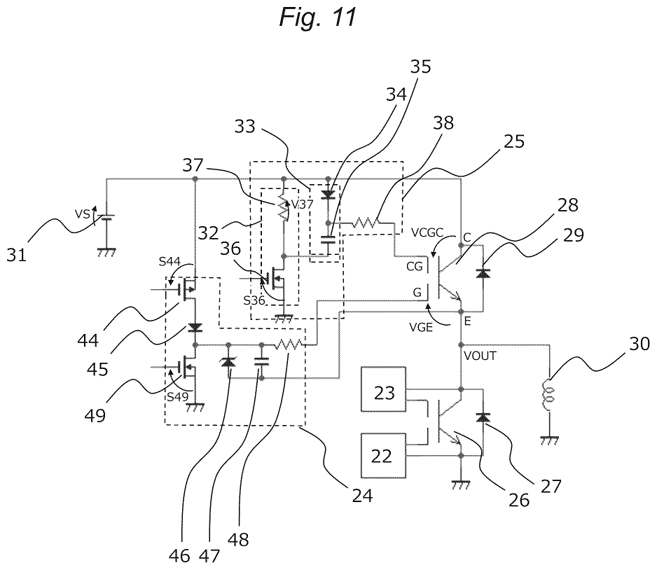

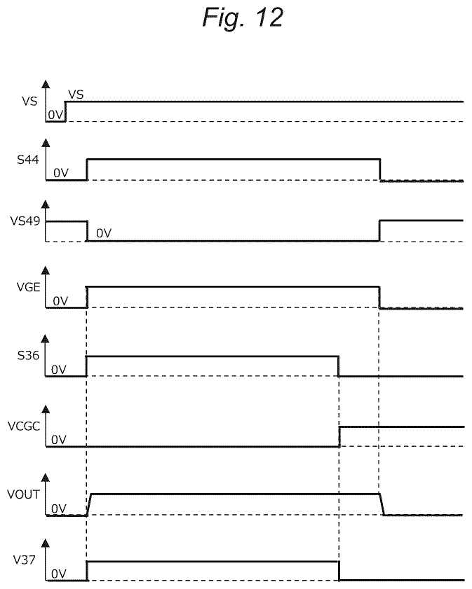

Next, referring to FIG. 11 and FIG. 12, a configuration of an upper-arm drive circuit in a fourth embodiment of the present invention and a control method thereof will be described. The fourth embodiment will describe a specific example of the gate driver 24 for driving the gate G of the CG-IGBT 28. The gate driver 24 includes a switching element 44, a backflow prevention element (diode) 45, a voltage limiting element (zener diode) 46, a capacitor 47, a gate delay circuit (resistor) 48, and a switching element 49.

The gate G of the CG-IGBT 28 serving as an upper-arm output element is connected to the main power supply 31 of the power conversion device via each of the switching element 44, the backflow prevention element (diode) 45, and the gate delay circuit (resistor) 48 and also connected to the reference potential (ground) of the power conversion device via each of the switching element 49 and the gate delay circuit (resistor) 48.

One terminal of the capacitor 47 is connected to the main power supply 31 of the power conversion device via each of the switching element 44 and the backflow prevention element (diode) 45, connected to the reference potential (ground) of the power conversion device via the switching element 49, and connected to the gate G of the CG-IGBT 28, which is the upper-arm output element, via the gate delay circuit (resistor) 48. Meanwhile, the other terminal of the capacitor 47 is connected to the output terminal VOUT of the power conversion device, and the voltage limiting element (zener diode) 46 is connected in parallel to both terminals of the capacitor 47.

As shown in FIG. 12, in the upper-arm drive circuit for the power conversion device in the fourth embodiment of the present invention, the main power supply 31 is turned ON first to increase a collector potential of the CG-IGBT 28 to the voltage VS of the main power supply 31. Next, when the switching element 44 is turned ON, charges are injected from the main power supply 31 of the power conversion device into the capacitor 47 via each of the switching element 44 and the backflow prevention element (diode) 45 to charge the capacitor 47. Since a voltage applied between both terminals of the capacitor 47 is limited by the voltage limiting element (zener diode) 46, there is no risk of breakdown due to an overvoltage. The charges charging the capacitor 47 are injected into the gate G of the CG-IGBT 28 via the gate delay circuit (resistor) 48 to increase the gate voltage VGE and turn ON the CG-IGBT 28, and a potential at the output terminal VOUT rises to the voltage VS of the main power supply 31 of the power conversion device.

At this time, by turning ON the switching element 36, a positive voltage V37 is generated across both ends of the resistor 37, and charges are stored in the capacitor 35. Thereafter, when the switching element 36 is turned OFF, no current flows in the resistor 37, the voltage V37 between the both ends of the resistor 37 drops to 0 V, and a potential at a junction between the resistor 37, the switching element 36, and the other terminal of the capacitor 35 becomes equal to the voltage VS of the main power supply 31 of the power conversion device. As a result, the charges stored in the capacitor 35 are injected into the collector gate CG of the CG-IGBT 28 via the gate delay circuit (resistor) 38 to increase the voltage of the collector gate CG, bring the collector gate of the CG-IGBT 28 into the ON state, and reduce the carrier density in the CG-IGBT 28.

Then, by turning OFF the switching element 44 and turning ON the switching element 49, the charges stored in the gate G of the CG-IGBT 28 are discharged to the reference potential (ground) of the power conversion device via each of the gate delay circuit (resistor) 48 and the switching element 49 to reduce the gate voltage VGE of the CG-IGBT 28 and turn OFF the CG-IGBT 28, and the output terminal VOUT drops to the reference potential of the power conversion device.

As described above, with the upper-arm drive circuit and the control method thereof in the fourth embodiment of the present invention, by turning ON the collector gate CG of the CG-IGBT 28 prior to the turning OFF of the CG-IGBT 28, it is possible to reduce the carrier density in the CG-IGBT 28, and consequently reduce the turn-off loss of the CG-IGBT 28.

### Fifth Embodiment

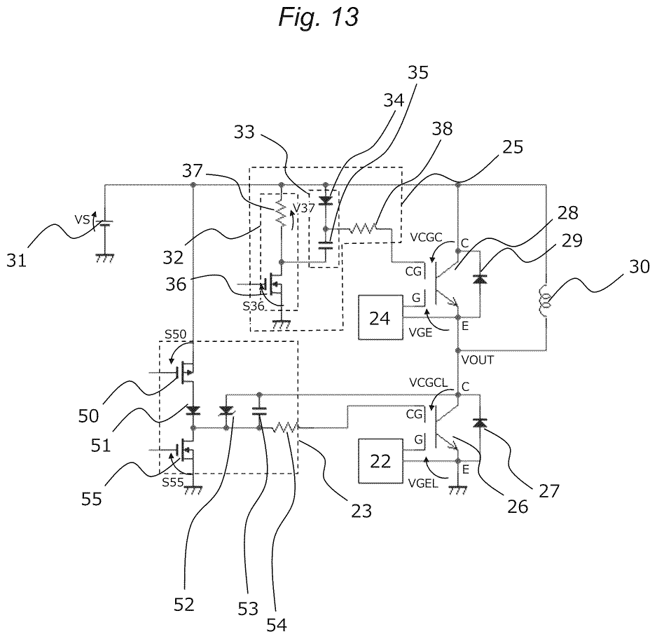

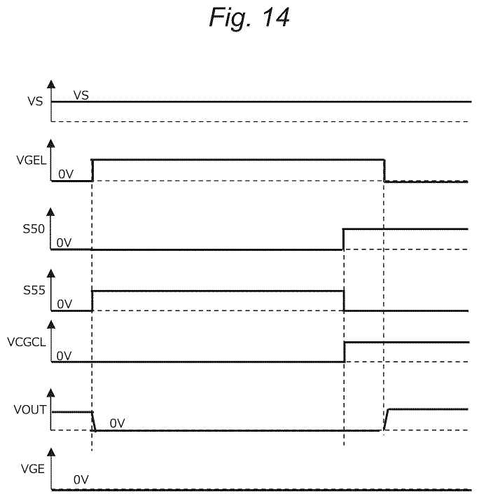

Next, referring to FIG. 13 and FIG. 14, configurations of an upper-arm drive circuit and a lower-arm drive circuit and control methods thereof in a fifth embodiment of the present invention will be described. In the fifth embodiment, a specific example of the gate driver 23 for driving the collector gate CG of the CG-IGBT 26, which is a lower-arm output element, will be described. The gate driver 23 is configured to include a switching element 50, a backflow prevention element (diode) 51, a voltage limiting element (zener diode) 52, a capacitor 53, a gate delay circuit (resistor) 54, and a switching element 55.

The collector gate CG of the CG-IGBT 26, which is the lower-arm output element, is connected to the main power supply 31 of the power conversion device via each of the switching element 50, the backflow prevention element (diode) 51, and the gate delay circuit (resistor) 54, and also connected to the reference potential (ground) of the power conversion device via each of the switching element 55 and the gate delay circuit (resistor) 54.

One terminal of the capacitor 53 is connected to the main power supply 31 of the power conversion device via each of the switching element 50 and the backflow prevention element (diode) 51, connected to the reference potential (ground) of the power conversion device via the switching element 55, and also connected to the collector gate CG of the CG-IGBT 28, which is a lower-arm output element, via the gate delay circuit (resistor) 54. Meanwhile, another terminal of the capacitor 53 is connected to the output terminal VOUT of the power conversion device, and the voltage limiting element (zener diode) 52 is connected in parallel to both terminals of the capacitor 53.

As shown in FIG. 14, in the upper-arm drive circuit and the lower-arm drive circuit for the power conversion device in the fifth embodiment of the present invention, when the main power supply 31 is turned ON, the collector voltage of the CG-IGBT 28, which is an upper-arm output element, increases to the voltage VS of the main power supply 31 and, in response to a lower-arm ON command signal input to the gate driver 22 of the lower-arm drive circuit in a state where the gate voltage VGE of the CG-IGBT 26, which is the lower-arm output element, is OFF (0 V), a gate voltage VGEL of the CG-IGBT 28, which is the upper-arm output element, increases to turn ON the CG-IGBT 26, and the potential at the output terminal VOUT drops to the reference potential (ground) of the power conversion device.

At this time, by turning ON the switching element 55, the collector gate CG of the CG-IGBT 26 is electrically conducted to the reference potential (ground) of the power conversion device to fix the collector gate CG of the CG-IGBT 26 to the OFF state. Thereafter, by turning OFF the switching element 55 and turning ON the switching element 50, charges are injected from the main power supply 31 of the power conversion device into the collector gate CG of the CG-IGBT 26 via each of the switching element 50, the backflow prevention element (diode) 51, and the gate delay circuit (resistance) 54 to increase a potential at the collector gate CG and turn ON the collector gate CG. At this time, even when an excessive current instantaneously flows in the switching element 50, the voltage limiting element (zener diode) 52 and the capacitor 53 can prevent the excessive voltage from being applied to the collector gate CG of the CG-IGBT 26. When the collector gate CG is turned ON, a carrier density in the CG-IGBT 26 decreases.

Then, in response to a lower-arm OFF command signal input to the gate driver 22, the gate voltage VGEL of the CG-IGBT 26, which is the lower-arm output element, drops to turn OFF the CG-IGBT 26, and the potential at the output terminal VOUT rises to the voltage VS of the main power supply 31 of the power conversion device.

As described above, with the upper-arm drive circuit and the lower-arm drive circuit in the power conversion device and the control methods thereof in the fifth embodiment of the present invention, by turning ON the collector gate CG of the CG-IGBT 26 prior to turning OFF of the CG-IGBT 26, it is possible to reduce the carrier density in the CG-IGBT 26 of the lower arm, and consequently reduce a turn-off loss of the CG-IGBT 26.

### REFERENCE SIGNS LIST

1 Support substrate
2 Buried oxide film
3 n-type semiconductor layer
4 p-base region
5 n-emitter region
6 p-anode region
7 n-buffer region
8 p-base region
9 n-cathode region
10 p-collector region
11 Channel region
12 Gate oxide film
13 Gate electrode
14 Channel region
15 Gate oxide film
16 Collector gate electrode
17 Emitter electrode
18 Collector electrode
19 N-type MOSFET
20 pnp-transistor
21 Embedded diode
22 Gate driver
23 Gate driver
24 Gate driver
25 Gate driver
26 CG-IGBT (lower-arm output element)
27 Freewheeling diode (lower-arm output element)
28 CG-IGBT (upper-arm output element)
29 Freewheeling diode (upper-arm output element)
30 Load (coil)
31 Main power supply
32 Charging/discharging control circuit
33 Charge storage circuit
34 Backflow prevention element (diode)
35 Capacitor
36 Switching element
37 Resistor
38 Gate delay circuit (resistor)
39 Switching element
40 Switching element
41 Switching element
42 Voltage limiting element (zener diode)
43 Voltage limiting element (zener diode)
44 Switching element
45 Backflow prevention element (diode)
46 Voltage limiting element (zener diode)
47 Capacitor
48 Gate delay circuit (resistor)
49 Switching element
50 Switching element
51 Backflow prevention element (diode)
52 Voltage limiting element (zener diode)
53 Capacitor
54 Gate delay circuit (resistor)
55 Switching element

1. A drive circuit for a power conversion device comprising a first CG-IGBT serving as an upper-arm output element and a second CG-IGBT serving as a lower-arm output element,
the drive circuit further comprising an upper-arm drive circuit that drives the first CG-IGBT and a lower-arm drive circuit that drives the second CG-IGBT,
the upper-arm drive circuit having a first gate driver that drives a collector gate of the first CG-IGBT and a second gate driver that drives a gate of the first CG-IGBT,
the lower-arm drive circuit having a third gate driver that drives a collector gate of the second CG-IGBT and a fourth gate driver that drives a gate of the second CG-IGBT,
the first gate driver having a charge storage circuit including a first capacitor and a first backflow prevention element and a charging/discharging control circuit including a first switching element and a first resistor,
one terminal of the first capacitor being connected to a main power supply of the power conversion device via the first backflow prevention element and connected to the collector gate of the first CG-IGBT,
another terminal of the first capacitor being connected to a reference potential of the power conversion device via the first switching element and connected to the main power supply of the power conversion device via the first resistor.

2. The drive circuit according to claim 1,
wherein the first backflow prevention element prevents a backflow of a current from the one terminal of the first capacitor to the main power supply of the power conversion device.

3. A drive circuit for a power conversion device comprising a first CG-IGBT serving as an upper-arm output element and a second CG-IGBT serving as a lower-arm output element,
the drive circuit further comprising an upper-arm drive circuit that drives the first CG-IGBT and a lower-arm drive circuit that drives the second CG-IGBT,
the upper-arm drive circuit having a first gate driver that drives a collector gate of the first CG-IGBT and a second gate driver that drives a gate of the first CG-IGBT,
the lower-arm drive circuit having a third gate driver that drives a collector gate of the second CG-IGBT and a fourth gate driver that drives a gate of the second CG-IGBT,
the first gate driver having a charge storage circuit including a first capacitor and a first backflow prevention element and a charging/discharging control circuit including a first switching element and a second switching element,
one terminal of the first capacitor being connected to a main power supply of the power conversion device via the first backflow prevention element and connected to the collector gate of the first CG-IGBT,
another terminal of the first capacitor being connected to a reference potential of the power conversion device via the first switching element and connected to the main power supply of the power conversion device via the second switching element.

4. The drive circuit according to claim 3,
wherein the first backflow prevention element prevents a backflow of a current from the one terminal of the first capacitor to the main power supply of the power conversion device.

5. The drive circuit according to claim 1,
wherein a first gate delay circuit is provided between the one terminal of the first capacitor and the collector gate of the first CG-IGBT.

6. The drive circuit according to claim 1,
wherein a third switching element is provided in parallel with the first backflow prevention element between the one terminal of the first capacitor and the main power supply of the power conversion device.

7. The drive circuit according to claim 1,
wherein a third switching element is provided between the one terminal of the first capacitor and the reference potential of the power conversion device.

8. The drive circuit according to claim 1,
wherein a first voltage limiting element is connected in parallel to the first capacitor.

9. The drive circuit according to claim 1,
wherein a first voltage limiting element is connected in parallel to the first resistor.

10. The drive circuit according to claim 1,
wherein the second gate driver includes a third switching element, a second backflow prevention element, a second voltage limiting element, a second capacitor, a first gate delay circuit, and a fourth switching element,
wherein one terminal of the second capacitor is connected to the main power supply of the power conversion device via each of the third switching element and the second backflow prevention element, connected to the reference potential of the power conversion device via the fourth switching element, and connected to the gate of the first CG-IGBT via the first gate delay circuit,
wherein another terminal of the second capacitor is connected to an output terminal of the power conversion device,
wherein the second voltage limiting element is connected in parallel to the second capacitor,
wherein the third gate driver includes a fifth switching element, a third backflow prevention element, a third voltage limiting element, a third capacitor, a second gate delay circuit, and a sixth switching element,
wherein one terminal of the third capacitor is connected to the main power supply of the power conversion device via each of the fifth switching element and the third backflow prevention element, connected to the reference potential of the power conversion device via the sixth switching element, and connected to the collector gate of the second CG-IGBT via the second gate delay circuit,
wherein another terminal of the third capacitor is connected to the output terminal of the power conversion device, and
wherein the third voltage limiting element is connected in parallel to the third capacitor.
